(19) United States
(12) Patent Application Publication
(10) Pub. No.: US 2026/0290652 A1
(43) Pub. Date: Sep. 24, 2026

(54) METHOD FOR FORMING ELECTRODE

(71) Applicant: JUSUNG ENGINEERING CO., LTD., Gwangju-Si, Gyeonggi-Do (KR)

(72) Inventors: Young Woon KIM, Gwangju-Si, Gyeonggi-Do (KR); Seung Min YEO, Gwangju-Si, Gyeonggi-Do (KR); Chul Joo HWANG, Gwangju-Si, Gyeonggi-Do (KR)

(21) Appl. No.: 19/490,867

(22) PCT Filed: Jun. 5, 2024
(86) PCT No.: PCT/KR2024/007710

§ 371 Date: Dec. 5, 2025

(30) Foreign Application Priority Data
Jun. 8, 2023 (KR) 10-2023-0073425

(51) Int. Cl. H01B 13/00; C23C 16/06; C23C 16/455

(52) U.S. Cl. CPC H01B 13/0036; C23C 16/06; C23C 16/45529; C23C 16/4554

(57) ABSTRACT

A method for forming an electrode of a semiconductor device according to an embodiment of the invention includes forming a ruthenium layer on a substrate by performing n times of a ruthenium layer formation cycle including spraying a ruthenium-containing precursor, and forming a metal layer on a ruthenium layer by performing m times of a metal layer formation cycle including spraying a metal-containing precursor, wherein a ruthenium layer formation cycle and a metal layer formation cycle are sequentially performed, or a ruthenium layer formation cycle and a metal layer formation cycle are sequentially performed and repeated two or more times.

Therefore, according to embodiments of the invention, in forming an electrode including a ruthenium layer and a copper layer, it is possible to improve adhesion between the ruthenium layer and the copper layer.

### TECHNICAL FIELD

The present disclosure relates to a method for forming an electrode, and peculiarly, to a method for forming an electrode, the method capable of improving electrical properties.

### BACKGROUND ART

In forming an electrode of a capacitor, the electrode is formed by depositing ruthenium (Ru) having excellent electrical conductivity. However, since ruthenium is a very expensive material, in terms of cost, there is a limit to forming an electrode by depositing only a ruthenium layer. Accordingly, an electrode is formed by deposing a thin ruthenium layer, and then depositing a copper layer, which is relatively inexpensive, on the ruthenium layer.

Meanwhile, the copper layer has poor adhesion with the ruthenium layer. Accordingly, there is a problem in that the copper layer is peeled off from the ruthenium layer, and therefore, electrical properties of the electrode are degraded.

[Prior Art Document] (Patent Document 1) Korean Patent Registration No. KR 10-0881728

### DISCLOSURE OF THE INVENTIVE CONCEPT

### Technical Problem

The present disclosure provides, in forming an electrode including a ruthenium layer and a copper layer, a method for forming an electrode, the method capable of suppressing or preventing the copper layer from being peeled off.

### Technical Solution

In accordance with an exemplary embodiment, a method for forming an electrode on a substrate includes forming a ruthenium layer on a substrate by performing n times of a ruthenium layer formation cycle including spraying a ruthenium-containing precursor, and forming a metal layer on the ruthenium layer by performing m times of a metal layer formation cycle including spraying a metal-containing precursor, wherein the metal layer formation cycle and the ruthenium layer formation cycle are sequentially performed, or the metal layer formation cycle and the ruthenium layer formation cycle are performed by being sequentially performed and repeated two or more times.

The method may further include forming a copper layer on the metal layer after the ruthenium layer formation cycle and the metal layer formation cycle are sequentially performed and repeated two or more times, wherein the forming of the copper layer may be performed n times.

The ruthenium layer formation cycle may include exposing the ruthenium layer to hydrogen plasma.

The method may further include exposing the ruthenium layer to hydrogen plasma, wherein the exposing of the ruthenium layer to hydrogen plasma may be performed between the ruthenium layer formation cycle and the metal layer formation cycle.

The metal layer formation cycle may include exposing the metal layer to hydrogen plasma.

The method may further include exposing the metal layer to hydrogen plasma, wherein the exposing of the metal layer to hydrogen plasma may be performed after the end of the metal layer formation cycle.

In accordance with another exemplary embodiment, a method for forming an electrode on a substrate includes forming a metal layer on a substrate by performing m times of a metal layer formation cycle including spraying a metal-containing precursor, and forming a ruthenium layer on the metal layer by performing n times of a ruthenium layer formation cycle including spraying a ruthenium-containing precursor, wherein the metal layer formation cycle and the ruthenium layer formation cycle are sequentially performed, or the metal layer formation cycle and the ruthenium layer formation cycle are performed by being sequentially performed and repeated two or more times.

The method may further include forming a copper layer on the ruthenium layer after the metal layer formation cycle and the ruthenium layer formation cycle are sequentially performed and repeated two or more times, wherein the forming of the copper layer may be performed n times.

The metal layer formation cycle may include exposing the metal layer to hydrogen plasma.

The method may further include exposing the metal layer to hydrogen plasma, wherein the exposing of the metal layer to hydrogen plasma may be performed between the metal layer formation cycle and the ruthenium layer formation cycle.

The ruthenium layer formation cycle may include exposing the ruthenium layer to hydrogen plasma.

The method may further include exposing the ruthenium layer to hydrogen plasma, wherein the exposing of the ruthenium layer to hydrogen plasma may be performed after the end of the ruthenium layer formation cycle.

In accordance with yet another exemplary embodiment of the inventive concept, a method for forming an electrode on a substrate includes forming a mixed layer containing ruthenium and a metal on a substrate by performing a cycle including spraying a ruthenium-containing precursor and a metal-containing precursor, wherein the cycle is performed and repeated one or more times.

The method may further include forming a copper layer on the mixed layer after the above-described cycle is performed and repeated two or more times, wherein the forming of the copper layer may be performed n times.

The above-described cycle may include exposing the mixed layer containing ruthenium and a metal to hydrogen plasma.

The method may further include exposing the mixed layer containing ruthenium and a metal to hydrogen plasma, wherein the exposing of the mixed layer containing ruthenium and a metal to hydrogen plasma may be performed after the end of the above-described cycle.

The metal-containing precursor may include at least one metal among tungsten, iridium, osmium, rhodium, platinum, silver, rhenium, or palladium.

### Advantageous Effects

According to embodiments of the inventive concept, in forming an electrode including a ruthenium layer and a copper layer, it is possible to improve adhesion between the ruthenium layer and the copper layer. Therefore, it is possible to suppress or prevent the copper layer from being peeled off or separated from the ruthenium layer. As a result, it is possible to lower specific resistance of the electrode, and to improve electrical conductivity.

### BRIEF DESCRIPTION OF THE DRAWINGS

FIG. 1 is a drawing conceptually showing a semiconductor device including an electrode formed by a method in accordance with embodiments;

FIG. 2 is a diagram illustrating a state in which a lower electrode in accordance with an exemplary embodiment is formed on a substrate;

(a) to (c) of FIG. 3 are process diagrams sequentially showing a method for forming a ruthenium layer in the lower electrode in accordance with the exemplary embodiment;

(a) to (c) of FIG. 4 are process diagrams sequentially showing a method for forming a metal layer in the lower electrode in accordance with the exemplary embodiment;

FIG. 5 is a drawing showing a method for forming a copper layer in the lower electrode in accordance with the exemplary embodiment;

FIG. 6 is a drawing illustrating a state in which a lower electrode in accordance with another exemplary embodiment is formed on a substrate; and

FIG. 7 is a view illustrating a state in which a lower electrode in accordance with yet another embodiment is formed on a substrate.

### MODE FOR CARRYING OUT THE INVENTIVE CONCEPT

Hereinafter, embodiments of the inventive concept will be described in more detail with reference to the accompanying drawings. However, the inventive concept is not limited to the embodiments disclosed below, but will be implemented in various forms different from each other, and the embodiments are merely to complete the inventive concept, and are provided to fully convey the scope of the inventive concept to those skilled in the art. The drawings may be exaggerated to describe the embodiments of the inventive concept, and like reference numerals in the drawings refer to like elements.

The inventive concept relates to a method for forming an electrode of a semiconductor device. More specifically, in forming an electrode including a ruthenium layer and a copper layer, the inventive concept relates to a method for forming an electrode of a semiconductor device, the method capable of improving adhesion between the ruthenium layer and the copper layer.

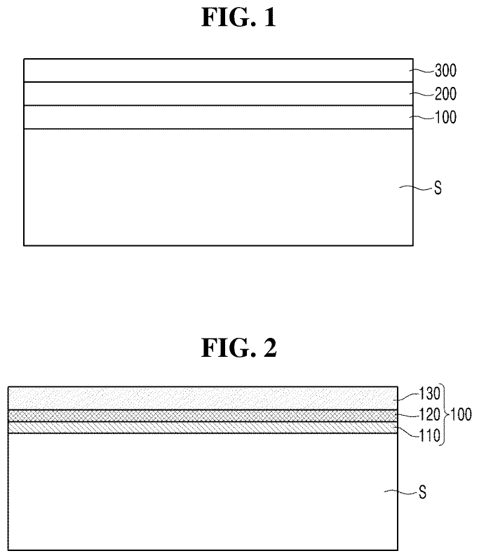

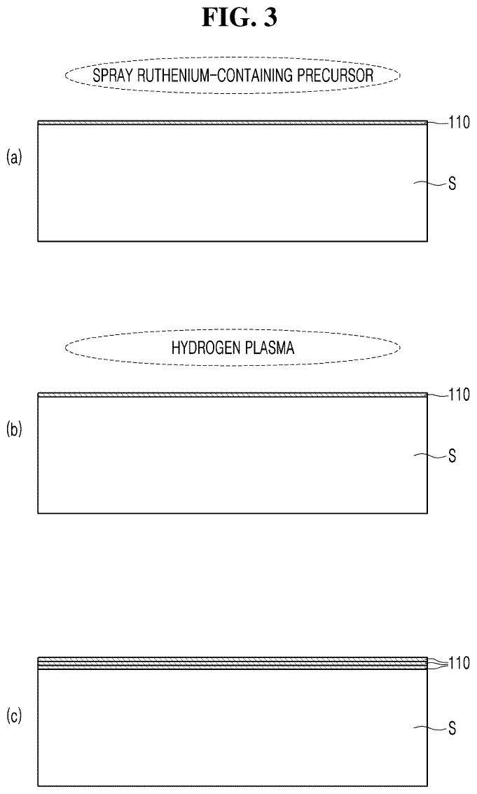

FIG. 1 is a drawing conceptually showing a semiconductor device including an electrode formed by a method in accordance with embodiments. FIG. 2 is a diagram illustrating a state in which a lower electrode in accordance with an exemplary embodiment is formed on a substrate.

The semiconductor device may be, for example, a capacitor. As illustrated in FIG. 1, such a capacitor may include a substrate S, a lower electrode 100 formed on the substrate S, a dielectric layer 200 formed on the lower electrode 100, and an upper electrode 300 formed on the dielectric layer 200.

The substrate S may be either a wafer or glass. In addition, if the substrate S is a wafer, the substrate S may be any one among a Si wafer, a GaAs wafer, and a SiGe wafer. Of course, as the wafer used as the substrate S, a variety of wafers other than the types of the wafers described above may be used.

The dielectric layer 200 may be formed of a dielectric material including a metal oxide. As a more specific example, the dielectric layer 200 may be formed of any one among ZrO₂, Al₂O₃, TiO₂, TaO₂, and HfO₂.

At least one of the lower electrode 100 and the upper electrode 300 is formed by the method in accordance with embodiments, and may include a copper(Cu) layer 130 and an underlayer formed on a lower side of the copper layer 130.

In addition, the underlayer may be at least one of a ruthenium (Ru) layer or a metal layer including a metal other than ruthenium (Ru). In addition, the underlayer may be a mixed layer including ruthenium (Ru) and another metal other than ruthenium (Ru).

Hereinafter, the lower electrode 100 in accordance with the exemplary embodiment will be described with reference to FIG. 2. Referring to FIG. 2, the lower electrode 100 may include a ruthenium layer 110 formed on the substrate S, the copper layer 130 formed on the ruthenium layer 110, and a metal layer 120 formed between the ruthenium layer 110 and the copper layer 130. Here, the metal layer 120 may be a layer of at least one of tungsten (W), iridium (Ir), osmium (Os), rhodium (Rh), platinum (Pt), silver (Ag), rhenium (Re), or palladium (Pd). That is, the metal layer 120 may be at least one of a tungsten layer, an iridium layer, an osmium layer, a rhodium layer, a platinum layer, a silver layer, a rhenium layer, or a palladium layer.

Hereinafter, a case where the metal layer 120 is a tungsten layer will be described as an example. In addition, for convenience of description, the tungsten layer will be described as having the same reference numeral ‘120’as that of the metal layer.

Referring to FIG. 2, the lower electrode 100 may include the ruthenium layer 110 formed on the substrate S, the copper layer 130 formed on the ruthenium layer 110, and a tungsten layer 120 formed between the ruthenium layer 110 and the copper layer 130.

Ruthenium (Ru) is a material with excellent electrical conductivity. However, ruthenium is a very expensive material, so that in terms of cost, it is difficult to form a thick ruthenium layer. Accordingly, an electrode is formed by forming a thin ruthenium layer, and then depositing a copper layer on the ruthenium layer. However, the copper layer has poor adhesion with the ruthenium layer. That is, the adhesion between the copper layer and the ruthenium layer is weak. Accordingly, there is a problem in that the copper layer is peeled off or separated from the ruthenium layer, and as a result, the resistance of the electrode increases and the electrical conductivity thereof decreases.

Therefore, in the exemplary embodiment, in order to improve the adhesion between the ruthenium layer 110 and the copper layer 130, the tungsten layer 120 is formed between the ruthenium layer 110 and the copper layer 130 as shown in FIG. 2. That is, the lower electrode 100 in accordance with the exemplary embodiment includes the ruthenium layer 110, the copper layer 130 formed on the ruthenium layer 110, and the tungsten layer 120 formed between the ruthenium layer 110 and the copper layer 130.

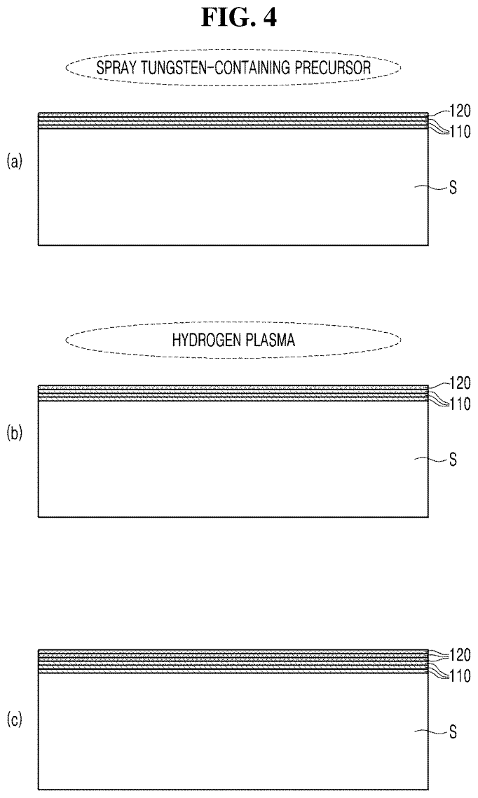

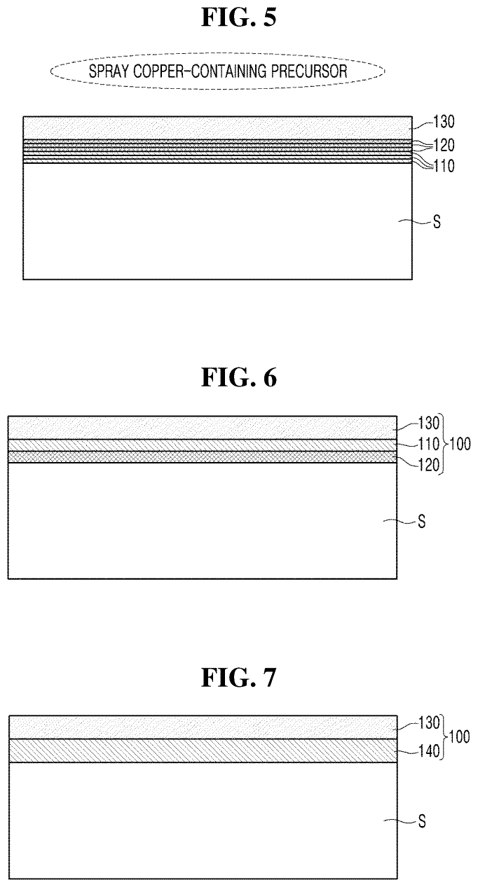

Hereinafter, with reference to FIG. 2, (a) to (c) of FIG. 3, (a) to (c) of FIG. 4, and FIG. 5, a method for forming a lower electrode on a substrate in accordance with the exemplary embodiment will be described.

(a) to (c) of FIG. 3 are process diagrams sequentially showing a method for forming a ruthenium layer in the lower electrode in accordance with the exemplary embodiment. (a) to (c) of FIG. 4 are process diagrams sequentially showing a method for forming a tungsten layer in the lower electrode in accordance with the exemplary embodiment. FIG. 5 is a drawing showing a method for forming a copper layer in the lower electrode in accordance with the exemplary embodiment.

First, the ruthenium layer 110 is formed on the substrate S. At this time, for example, the ruthenium layer 110 may be formed by an atomic layer deposition method. Referring to (a) to (c) of FIG. 3, the forming of the ruthenium layer 110 may include depositing the ruthenium layer 110 on the substrate S by spraying a precursor containing ruthenium (Ru) toward the substrate S (a ruthenium-containing precursor spraying step), and exposing the ruthenium layer 110 to hydrogen plasma (a hydrogen plasma exposure step).

In addition, the ‘ruthenium-containing precursor spraying step—hydrogen plasma exposure step’ may be set as one cycle (hereinafter, a ruthenium layer formation cycle CY_{Ru}). That is, the forming of the ruthenium layer 110 may include the ruthenium layer formation cycle CY_{Ru}, and the ruthenium layer formation cycle CY_{Ru} may include the spraying of the ruthenium-containing precursor and the exposing of the ruthenium layer 110 to hydrogen plasma.

In addition, the forming of the ruthenium layer 110 may further include at least one of spraying a purge gas between the ruthenium-containing precursor spraying step and the hydrogen plasma exposure step (a primary purge step) and spraying a purge gas after the hydrogen plasma exposure step (a secondary purge step). Here, an argon (Ar) gas may be used as the purge gas. In this case, the ‘ruthenium-containing precursor spraying step primary purge step—hydrogen plasma exposure step—secondary purge step’ may be set as one cycle (the ruthenium layer formation cycle CY_{Ru}). That is, the forming of the ruthenium layer 110 may include the ruthenium layer formation cycle CY_{Ru}, and the ruthenium layer formation cycle CY_{Ru} may include the ruthenium-containing precursor spraying step, the primary purge step, the hydrogen plasma exposure step, and the secondary purge step. At this time, in the ruthenium layer formation cycle CY_{Ru}, at least one of the primary purge step and the secondary purge step may be omitted.

In addition, the above-described ruthenium layer formation cycle CY_{Ru} may be performed n times (n: 1, 2, 3, . . . ). That is, the forming of the ruthenium layer 110 may include one time (n=1) or two or more times (n≥2) of the ruthenium layer formation cycle CY_{Ru}. Here, two or more times may mean a plurality of times.

Hereinafter, the ruthenium layer formation cycle CY_{Ru} will be described in more detail.

In the spraying of the ruthenium-containing precursor, a precursor containing or including ruthenium (Ru) is sprayed toward the substrate S as shown in FIG. 3. That is, the precursor containing ruthenium is sprayed into a chamber in which the substrate S is charged. Here, a precursor raw material containing ruthenium (Ru) may be, for example, bis(ethylcyclopentadienyl)ruthenium ((EtCp)₂Ru). Of course, the precursor raw material containing ruthenium (Ru) is not limited to the above-described material, and a variety of precursor raw materials containing ruthenium (Ru) may be used.

If the precursor containing ruthenium (Ru) is sprayed toward the substrate S, the precursor is deposited or adsorbed on one surface of the substrate S, so that the ruthenium layer 110, which is a film or layer containing ruthenium, is deposited as shown in (a) of FIG. 3.

When the spraying of the precursor is completed, the primary purge is performed by spraying a purge gas into the chamber in which the substrate S is charged. At this time, for example, an argon (Ar) gas may be used as the purge gas.

When the primary purge is completed, the ruthenium layer 110 is exposed to hydrogen plasma as shown in (b) of FIG. 3. That is, hydrogen plasma is generated inside the chamber in which the substrate S with the ruthenium layer 110 is charged, so that the ruthenium layer 110 is exposed to the hydrogen plasma. To this end, radio frequency (RF) power is applied to at least one of a susceptor on which the substrate S is seated inside the chamber and a spraying part for spraying a gas into the chamber. In addition, a gas including hydrogen (H₂) is used as a gas for generating plasma. More specifically, the gas for generating plasma may be a hydrogen (H₂) gas. As described above, when the RF power is applied and the gas including hydrogen (H₂) is sprayed, plasma containing the hydrogen (H₂), that is, hydrogen plasma, may be generated inside the chamber. Accordingly, the substrate S with the ruthenium layer 110 is exposed to the hydrogen plasma.

As described above, the hydrogen plasma exposure step is a step in which hydrogen plasma is generated to expose the ruthenium layer 110 to the hydrogen plasma. Therefore, the hydrogen plasma exposure step may be named as a hydrogen plasma generation step.

The ruthenium-containing precursor may contain impurities which increase specific resistance of the ruthenium layer 110. For example, the ruthenium-containing precursor may include at least one ligand of C (carbon) and O (oxygen) other than ruthenium (Ru). Accordingly, the ruthenium layer 110 deposited by spraying the ruthenium-containing precursor may contain or include at least one ligand of C (carbon) and O (oxygen), and the ligand acts as the impurity which increases the specific resistance of the ruthenium layer 110. Therefore, it is preferable that the impurity included in the ruthenium layer 110 is removed.

Therefore, in an embodiment, the ruthenium-containing precursor is sprayed to deposit the ruthenium layer 110, and then, the ruthenium layer 110 is exposed to hydrogen plasma to remove impurities. If the ruthenium layer 110 is exposed to the hydrogen plasma, the impurities included in the ruthenium layer 110 react with hydrogen. As a result, at least one of impurities of C (carbon) and O (oxygen) included in the ruthenium layer 110 reacts with the hydrogen and becomes a gas and escapes from the ruthenium layer 110. Therefore, the content of at least one of the impurities of C (carbon) and O (oxygen) included in the ruthenium layer 110 is reduced. As a result, the specific resistance of the ruthenium layer 110 may be lowered.

Thereafter, the secondary purge is performed by spraying a purge gas into the chamber in which the substrate S is charged. At this time, the same gas as the gas used in the primary purge may be used as the purge gas, and for example, an argon (Ar) gas may be used.

A process including the ruthenium-containing precursor spraying step, the primary purge step, the hydrogen plasma exposure step, and the secondary purge step described above may be set as one ruthenium layer formation cycle CY_{Ru}. That is, the cycle CY_{Ru} for forming the ruthenium layer 110 may include the ‘ruthenium-containing precursor spraying step—primary purge step—hydrogen plasma exposure step—secondary purge step.’ In addition, the ruthenium layer formation cycle CY_{Ru} may be continuously performed a plurality of times to form the ruthenium layer 110 with a target thickness. At this time, if the ruthenium layer formation cycle CY_{Ru} is performed a plurality of times, a plurality of ruthenium layers 110 are deposited on the substrate S as shown in (c) of FIG. 3 and form one ruthenium layer 110 as shown in FIG. 2.

In (c) of FIG. 3, the plurality of the ruthenium layers 110 are separately shown in order to distinguish the ruthenium layer 110 formed by each of the plurality of ruthenium layer formation cycles CY_{Ru}, but the stacked plurality of ruthenium layers 110 may be integrated.

Next, the tungsten layer 120 is formed on the ruthenium layer 110. At this time, for example, the tungsten layer 120 may be formed by an atomic layer deposition method. Referring to (a) to (c) of FIG. 4, the forming of the tungsten layer 120 may include forming the tungsten layer 120 on the ruthenium layer 110 by spraying a precursor containing tungsten (W) toward the substrate S (a tungsten-containing precursor spraying step), and exposing the tungsten layer 120 to hydrogen plasma (a hydrogen plasma exposure step).

In addition, the ‘tungsten-containing precursor spraying step—hydrogen plasma exposure step’ may be set as one cycle (hereinafter, a tungsten layer formation cycle CY_{W}). That is, the forming of the tungsten layer 120 may include the tungsten layer formation cycle CY_{W}, and the tungsten layer formation cycle CY_{W} may include the spraying of the tungsten-containing precursor and the exposing of the tungsten layer 120 to hydrogen plasma.

In addition, the forming of the tungsten layer 120 may further include at least one of spraying a purge gas between the tungsten-containing precursor spraying step and the hydrogen plasma exposure step (a primary purge step) and spraying a purge gas after the hydrogen plasma exposure step (a secondary purge step). In addition, the ‘tungsten-containing precursor spraying step—primary purge step—hydrogen plasma exposure step secondary purge step’ may be set as one cycle (the tungsten layer formation cycle CY_{W}). That is, the forming of the tungsten layer 120 may include the tungsten layer formation cycle CY_{W}, and the tungsten layer formation cycle CY_{W} may include the tungsten-containing precursor spraying step, the primary purge step, the hydrogen plasma exposure step, and the secondary purge step. At this time, in the tungsten layer formation cycle CY_{W}, at least one of the primary purge step and the secondary purge step may be omitted.

In addition, the above-described tungsten layer formation cycle CY_{W} may be performed m times (m: 1, 2, 3, . . . ). That is, the forming of the tungsten layer 120 may include one time (m=1) or two or more times (m≥2) of the tungsten layer formation cycle CY_{W}. Here, two or more times may mean a plurality of times.

Hereinafter, the tungsten layer formation cycle CY_{W} will be described in more detail. At this time, the same descriptions as those described in the ruthenium layer formation cycle CY_{Ru} will be omitted or briefly described.

In the spraying of the tungsten-containing precursor, a precursor containing or including tungsten (W) is sprayed toward the ruthenium layer 110 shown in (a) of FIG. 4. That is, the precursor containing tungsten is sprayed into a chamber in which the substrate S is charged. Here, a precursor raw material containing tungsten (W) may be, for example, tungsten hexafluoride (WF₆). Of course, the precursor raw material containing tungsten (W) is not limited to the above-described example, and a variety of precursor raw materials containing tungsten (W) may be used. If the precursor containing tungsten (W) is sprayed, the precursor is deposited or adsorbed onto the ruthenium layer 110, so that the tungsten layer 120, which is a film or layer containing tungsten, is deposited as shown in (a) of FIG. 4.

When the spraying of the precursor is completed, the primary purge is performed by spraying a purge gas into the chamber in which the substrate S is charged. At this time, the same gas as the gas used in the ruthenium layer formation cycle CY_{Ru} may be used as the purge gas, and for example, an argon (Ar) gas may be used as the purge gas.

When the primary purge is completed, the tungsten layer 120 is exposed to hydrogen plasma as shown in (b) of FIG. 4. The hydrogen plasma is generated in the same manner as described in the ruthenium layer formation cycle CY_{Ru}, and thus, the description thereof is omitted.

The tungsten-containing precursor may contain at least one of impurities which increase the specific resistance, for example, C (carbon) and O (oxygen). Accordingly, the tungsten layer 120 formed by spraying the tungsten-containing precursor may contain or include at least one of the impurities of C (carbon) and O (oxygen), and the above-described impurity acts as the impurity which increases the specific resistance of the tungsten layer 120. Therefore, it is preferable that the impurity included in the tungsten layer 120 is removed.

Accordingly, in an embodiment, the tungsten-containing precursor is sprayed to deposit the tungsten layer 120, and then, the tungsten layer 120 is exposed to hydrogen plasma to remove impurities. If the tungsten layer 120 is exposed to the hydrogen plasma, the impurities included in the tungsten layer 120 react with hydrogen. That is, at least one of the impurities of C (carbon) and O (oxygen) included in the tungsten layer 120 reacts with the hydrogen and becomes a gas and escapes from the tungsten layer 120. Therefore, the content of at least one of the impurities of C (carbon) and O (oxygen) included in the tungsten layer 120 is reduced. As a result, the specific resistance of the tungsten layer 120 may be lowered.

Thereafter, the secondary purge is performed by spraying a purge gas, e.g., an argon (Ar) gas, into the chamber in which the substrate S is charged.

A process including the tungsten-containing precursor spraying step, the primary purge step, the hydrogen plasma exposure step, and the secondary purge step described above may be set as one tungsten layer formation cycle CY_{W}. That is, the cycle CY_{W} for forming the tungsten layer 120 may include the ‘tungsten-containing precursor spraying step—primary purge step—hydrogen plasma exposure step—secondary purge step.’ In addition, the tungsten layer formation cycle CY_{W} may be performed one time or continuously performed two or more times to form the tungsten layer 120 with a target thickness.

In (c) of FIG. 4, a plurality of tungsten layers 120 are separately shown in order to distinguish the tungsten layer 120 formed by each of the plurality of tungsten layer formation cycles CY_{W}, but the stacked plurality of tungsten layers 120 may be integrated.

In the above descriptions, the forming of the ruthenium layer 110 and the forming of the tungsten layer 120 are described to include exposing each of the ruthenium layer 110 and the tungsten layer 120 to hydrogen plasma. However, the forming of the ruthenium layer 110 and the forming of the tungsten layer 120 may not include the hydrogen plasma exposure step. That is, in forming the ruthenium layer 110 and the tungsten layer 120, the exposing of each of the ruthenium layer 110 and the tungsten layer 120 to hydrogen plasma may be omitted.

Next, the copper layer 130 is formed on the tungsten layer 120. At this time, the copper layer 130 may be formed by a chemical vapor deposition (CVD) method. In describing the above with a more specific example, a precursor raw material containing copper (Cu) is sprayed into a chamber in which the substrate S having the ruthenium layer 110 and the tungsten layer 120 is charged (a copper-containing precursor spraying step). At this time, it is preferable that the temperature of the substrate S is controlled to be, for example, 150° C. to 300° C. In addition, the precursor raw material containing copper (Cu) may be, for example, hexafluoroacetylacetonate (hfac) Cu(I) 3,3-dimethyl-1-butene (DMB). Of course, the precursor raw material containing copper (Cu) is not limited to the above-described example, and a variety of precursor raw materials containing copper (Cu) may be used. As described above, the forming of the copper layer may be performed n times (n: 1, 2, 3, . . . ). That is, the forming of the copper layer may be performed one time (n=1) or two or more times (n≥2). Here, two or more times may mean a plurality of times.

As described above, the copper layer 130 is formed by being deposited on the tungsten layer 120. That is, before forming the copper layer 130, the tungsten layer 120 is formed on the ruthenium layer 110, and the copper layer 130 is formed on the tungsten layer 120. In other words, the copper layer 130 is not directly formed on the ruthenium layer 110, and after the tungsten layer 120 is formed on the ruthenium layer 110, the copper layer 130 is formed on the tungsten layer 120. As a result, the copper layer 130 is not in direct contact with the ruthenium layer 110, and is in contact with the tungsten layer 120. Compared to ruthenium, copper has high binding force with tungsten. Accordingly, compared to directly forming the copper layer 130 on the ruthenium layer 110, if the copper layer 130 is formed on the tungsten layer 120, the copper layer 130 has increased adhesion with the tungsten layer 120, which is an underlayer. Therefore, it is possible to suppress or prevent the copper layer 130 from being peeled off or separated from the underlayer. That is, it is possible to suppress or prevent the copper layer 130 from being peeled off or separated from the tungsten layer 120. As a result, it is possible to improve electrical properties of the lower electrode 100 formed by depositing the ruthenium layer 110, the tungsten layer 120, and the copper layer 130. That is, it is possible to lower the resistance of the lower electrode 100, and improve the electrical conductivity thereof.

In the above-described exemplary embodiment, it has been described that the ruthenium layer formation cycle CY_{Ru} is continuously performed a predetermined number of times to form the ruthenium layer 110, and then the tungsten layer formation cycle CY_{W} is continuously performed a predetermined number of times to form the tungsten layer 120. As a result, as illustrated in FIG. 2, the lower electrode 100 has a structure including one ruthenium layer 110 formed by performing the ruthenium layer formation cycle CY_{Ru} a plurality of times, one tungsten layer 120 formed by performing the tungsten layer formation cycle CY_{W} a plurality of times, and the copper layer 130 formed on the tungsten layer 120.

However, the inventive concept is not limited thereto, and the ruthenium layer formation cycle CY_{Ru} and the tungsten layer formation cycle CY_{W} may be alternatively performed a plurality of times. That is, the ‘ruthenium layer formation cycle CY_{Ru}, the tungsten layer formation cycle CY_{W}, the ruthenium layer formation cycle CY_{Ru}, the tungsten layer formation cycle CY_{W}, the ruthenium layer formation cycle CY_{Ru}, the tungsten layer formation cycle CY_{W}, . . . , the tungsten layer formation cycle CY_{W}’ may be performed. As a result, the lower electrode 100 may be prepared in a structure including a plurality of ruthenium layers 110, a plurality of tungsten layers 120, and a copper layer 130 formed on the uppermost tungsten layer 120, wherein the ruthenium layer 110 and the tungsten layer 120 are alternately stacked.

FIG. 6 is a drawing illustrating a state in which a lower electrode in accordance with another exemplary embodiment is formed on a substrate.

In the above-described exemplary embodiment, the lower electrode 100 in which the tungsten layer 120 is formed between the ruthenium layer 110 and the copper layer 130 has been described as an example. However, the inventive concept is not limited thereto, and a tungsten layer 120 may be formed on a lower side of a ruthenium layer 110 as in another exemplary embodiment illustrated in FIG. 6. That is, the tungsten layer 120 may be first formed, and then the ruthenium layer 110 may be formed on the tungsten layer 120, followed by forming the copper layer 130 on the ruthenium layer 110. In other words, the lower electrode 100 in accordance with another exemplary embodiment may include the tungsten layer 120 formed on a substrate S, the ruthenium layer 110 formed on the tungsten layer 120, and a copper layer 130 formed on the ruthenium layer 110.

Methods for forming the tungsten layer 120, the ruthenium layer 110, and the copper layer 130 may be similar to or the same as the methods described in the exemplary embodiment described above, except for the order of forming each layer. In addition, the method for forming the copper layer 130 may be similar to or the same as the above-described method for forming the copper layer 130. Therefore, in describing a method for forming the lower electrode 100 in accordance with another embodiment below, the same contents as those described in the exemplary embodiment will be omitted, or briefly described.

First, the tungsten layer 120 is deposited on the substrate S by spraying a precursor containing tungsten (W) toward the substrate S. Next, hydrogen plasma is generated to expose the tungsten layer 120 to the hydrogen plasma. As a result, impurities contained in the tungsten layer 120 may be removed. In addition, a tungsten layer formation cycle CY_{W} including the spraying of the precursor containing tungsten (W) and the exposing of the tungsten layer 120 to hydrogen plasma may be performed a plurality of times to form the tungsten layer 120 having a target thickness on the substrate S. Here, in the forming of the tungsten layer 120, the exposing of the tungsten layer 120 to hydrogen plasma may be omitted.

Next, the ruthenium layer 110 is deposited on the tungsten layer 120 by spraying a precursor containing ruthenium (Ru) toward the tungsten layer 120. Thereafter, hydrogen plasma is generated to expose the ruthenium layer 110 to the hydrogen plasma. As a result, impurities contained in the ruthenium layer 110 may be removed. In addition, a ruthenium layer formation cycle CY_{Ru} including the spraying of the precursor containing ruthenium (Ru) and the exposing of the ruthenium layer 110 to hydrogen plasma may be performed a plurality of times to form the ruthenium layer 110 having a target thickness on the tungsten layer 120.

In addition, the copper layer 130 is formed on the ruthenium layer 110.

As described above, the forming of the ruthenium layer 110 includes the spraying of the precursor containing ruthenium (Ru) and the exposing of the ruthenium layer 110 to hydrogen plasma. At this time, if the ruthenium layer 110 is exposed to hydrogen plasma, some of tungsten atoms contained in the tungsten layer 120 may diffuse or move into the ruthenium layer 110. That is, by the hydrogen plasma, impurities contained in the ruthenium layer 110 may be removed, and some of the tungsten atoms contained in the tungsten layer 120 may diffuse or move into the ruthenium layer 110. Therefore, the ruthenium layer 110 in accordance with another exemplary embodiment may further contain tungsten (W) other than ruthenium (Ru). In other words, the ruthenium layer 110 may be doped with tungsten (W). The ruthenium layer 110 doped with tungsten (W) as described above contains tungsten (W) other than ruthenium (Ru), so that the ruthenium layer 110 may be defined as a ruthenium layer containing tungsten.

As described above, by forming the copper layer 130 on the ruthenium layer 110 containing ruthenium and tungsten, it is possible to suppress or prevent the copper layer 130 from being peeled off or separated from the ruthenium layer 110, which is an underlayer. That is, compared to a case in which the copper layer 130 is directly formed on the ruthenium layer 110 not doped with tungsten, if the copper layer 130 is formed on the ruthenium layer 110 doped with tungsten as in another exemplary embodiment, the adhesion of the copper layer 130 to an underlayer increases. This is because the ruthenium layer 110 is doped with or contains tungsten, which has higher binding force to copper than ruthenium. Accordingly, it is possible to suppress or prevent the copper layer 130 from being peeled off or separated from the ruthenium layer 110, which is the underlayer. Therefore, it is possible to improve electrical properties of the lower electrode 100 formed by depositing the tungsten layer 120, the ruthenium layer 110, and the copper layer 130.

In the above-described another exemplary embodiment, it has been described that the tungsten layer formation cycle CY_{W} is continuously performed a predetermined number of times to form the tungsten layer 120, and then the ruthenium layer formation cycle CY_{Ru} is continuously performed a predetermined number of times to form the ruthenium layer 110. As a result, as illustrated in FIG. 6, the lower electrode 100 has a structure including one tungsten layer 120 formed by performing the tungsten layer formation cycle CY_{W} a plurality of times, one ruthenium layer 110 formed by performing the ruthenium layer formation cycle CY_{Ru} a plurality of times, and the copper layer 130 formed on the ruthenium layer 110.

However, the inventive concept is not limited thereto, and the tungsten layer formation cycle CY_{W} and the ruthenium layer formation cycle CY_{Ru} may be alternatively performed a plurality of times. That is, the ‘tungsten layer formation cycle CY_{W}, the ruthenium layer formation cycle CY_{Ru}, the tungsten layer formation cycle CY_{W}, the ruthenium layer formation cycle CY_{Ru}, the tungsten layer formation cycle CY_{W}, the ruthenium layer formation cycle CY_{Ru}, . . . , the ruthenium layer formation cycle CY_{Ru}’ may be performed. As a result, the lower electrode 100 may be prepared in a structure including a plurality of tungsten layers 120, a plurality of ruthenium layers 110, and a copper layer 130 formed on the uppermost ruthenium layer 110, wherein the tungsten layer 120 and the ruthenium layer 110 are alternately stacked.

In the exemplary embodiment and another exemplary embodiment described above, it has been described that each of the ruthenium layer formation cycle CY_{Ru} and the tungsten layer formation cycle CY_{W} includes the hydrogen plasma exposure step. However, the inventive concept is not limited thereto, and each of the ruthenium layer formation cycle CY_{Ru} and the tungsten layer formation cycle CY_{W} may not include the hydrogen plasma exposure step, and the hydrogen plasma exposure step may be separately performed.

That is, in the exemplary and another exemplary embodiments, the ruthenium layer formation cycle CY_{Ru} includes the ‘ruthenium-containing precursor spraying step—purge step,’ and the tungsten layer formation cycle CY_{W} includes the ‘tungsten-containing precursor spraying step—purge step,’ wherein the two cycles may not include the hydrogen plasma exposure step. In addition, in the exemplary embodiment, hydrogen plasma may be generated between the ruthenium layer formation cycle CY_{Ru} and the tungsten layer formation cycle CY_{W} to expose the ruthenium layer to the hydrogen plasma, and after the tungsten layer formation cycle CY_{W} is completed, hydrogen plasma may be generated to expose the tungsten layer to the hydrogen plasma.

Of course, the inventive concept is not limited thereto, and each of the ruthenium layer formation cycle CY_{Ru} and the tungsten layer formation cycle CY_{W} may include the hydrogen plasma exposure step, and the hydrogen plasma exposure step may be separately further performed. That is, in the exemplary and another exemplary embodiments, the ruthenium layer formation cycle CY_{Ru} includes the ‘ruthenium-containing precursor spraying step—primary purge step—plasma exposure step—secondary purge step,’ and the tungsten layer formation cycle CY_{W} includes the ‘tungsten-containing precursor spraying step—primary purge step—plasma exposure step—secondary purge step.’ In addition, in the exemplary embodiment, exposing ruthenium layer to hydrogen plasma may be included between the ruthenium layer formation cycle CY_{Ru} and the tungsten layer formation cycle CY_{W}, and after the tungsten layer formation cycle CY_{W} is completed, exposing the tungsten layer to hydrogen plasma may be included. In addition, in another exemplary embodiment, exposing tungsten layer to hydrogen plasma may be included between the tungsten layer formation cycle CY_{W} and the ruthenium layer formation cycle CY_{Ru}, and after the ruthenium layer formation cycle CY_{Ru} is completed, exposing the ruthenium layer to hydrogen plasma may be included.

In the exemplary and another exemplary embodiments described above, a metal layer is described as a tungsten layer as an example. However, the metal layer may be any one among an iridium layer, an osmium layer, a rhodium layer, a platinum layer, a silver layer, a rhenium layer, and a palladium layer. To this end, a precursor containing any one metal among iridium (Ir), osmium (Os), rhodium (Rh), platinum (Pt), silver (Ag), rhenium (Re), and palladium (Pd) may be sprayed to form the metal layer.

FIG. 7 is a view illustrating a state in which a lower electrode in accordance with yet another embodiment is formed on a substrate.

In the exemplary and another embodiments described above, the lower electrode 100 in which two layers different from each other, that is, the ruthenium layer 110 and the tungsten layer 120, are deposited on a lower side of the copper layer 130 has been described. However, the inventive concept is not limited thereto, and a single underlayer may be formed on the lower side of the copper layer 130, and the single underlayer may be a layer containing ruthenium (R) and tungsten (W) (hereinafter, a mixed layer 140). That is, a lower electrode 100 in accordance with yet another embodiment may include the mixed layer 140 formed on a substrate S and containing ruthenium (Ru) and tungsten (W), and a copper layer 130 formed on the mixed layer 140.

A method for forming the mixed layer 140 may be similar to or the same as to the method for forming the ruthenium layer 110 and the method for forming the tungsten layer 120, other than spraying precursors together, which respectively contains ruthenium (Ru) and tungsten (W), in a precursor spraying step. In addition, a method for forming the copper layer 130 may be similar to or the same as the method described in the exemplary and another exemplary embodiments. Therefore, in describing a method for forming the lower electrode 100 in accordance with yet another embodiment below, the same contents as those described in the exemplary and another exemplary embodiments will be omitted, or briefly described.

First, a ruthenium (Ru)-containing precursor and a tungsten (W)-containing precursor are sprayed toward the substrate S. At this time, the ruthenium-containing precursor and the tungsten-containing precursor may be prepared and sprayed separately, or the ruthenium-containing precursor and the tungsten-containing precursor may be mixed and sprayed. When the ruthenium-containing precursor and the tungsten-containing precursor are sprayed onto the substrate S, a mixed layer 140 containing ruthenium and tungsten is deposited on the substrate S. Next, hydrogen plasma is generated and the mixed layer 140 is exposed to the hydrogen plasma. As a result, impurities contained in the mixed layer 140 may be removed. In addition, a mixed layer formation cycle CYₘ including the spraying of the ruthenium-containing precursor and the tungsten-containing precursor and the exposing of the mixed layer 140 to hydrogen plasma may be performed a plurality of times to form the mixed layer 140 having a target thickness on the substrate S. Since the mixed layer 140 contains ruthenium and tungsten, the mixed layer may be defined as a layer containing tungsten and ruthenium.

Thereafter, the copper layer 130 is formed on the mixed layer 140. As such, the copper layer 130 is deposited and formed on the mixed layer 140 containing ruthenium and tungsten. Therefore, it is possible to suppress or prevent the copper layer 130 from being peeled off or separated from the mixed layer 140, which is an underlayer. That is, compared to a case in which the copper layer 130 is directly formed on the ruthenium layer 110 not containing tungsten, if the copper layer 130 is formed on the mixed layer 140 further containing tungsten in addition to ruthenium as in yet another exemplary embodiment, the adhesion of the copper layer 130 to an underlayer increases. Accordingly, it is possible to suppress or prevent the copper layer 130 from being peeled off or separated from the mixed layer 140, which is the underlayer. Therefore, it is possible to improve electrical properties of the lower electrode 100 formed by depositing the mixed layer 140 and the copper layer 130.

In the above-described yet another exemplary embodiment, it has been described that the mixed layer formation cycle CYₘ includes the hydrogen plasma exposure step. However, the inventive concept is not limited thereto, and the mixed layer formation cycle CYₘ may not include the hydrogen plasma exposure step, and the hydrogen plasma exposure step may be separately performed. That is, the mixed layer formation cycle CYₘ includes the ‘ruthenium-containing precursor and tungsten-containing precursor spraying step—purge step,’ and after the mixed layer formation cycle CYₘ is completed, hydrogen plasma may be generated to expose the mixed layer to the hydrogen plasma.

Of course, the inventive concept is not limited thereto, and the mixed layer formation cycle CYₘ may include the hydrogen plasma exposure step, and after the mixed layer formation cycle CYₘ is completed, hydrogen plasma may be generated to expose the mixed layer to the hydrogen plasma once again.

In the above, it has been described that the lower electrode 100 of a semiconductor device or capacitor is formed by the methods in accordance with the embodiments. However, the inventive concept is not limited thereto, and by the electrode formation methods in accordance with the embodiments, the upper electrode 300 of a semiconductor device or capacitor may be formed, or both the lower electrode 100 and the upper electrode 300 may be formed. In addition, the electrode formation method in accordance with the embodiments may be applied in forming various other electrodes or conductive films among components of a semiconductor device, in addition to the upper electrode 300 and the lower electrode 100.

In the above-described embodiments, in forming an electrode including the ruthenium layer 110 and the copper layer 130, the tungsten layer 120 may be formed between the ruthenium layer 110 and the copper layer 130, or the ruthenium layer doped with tungsten or the mixed layer containing ruthenium and tungsten may be formed, followed by forming the copper layer 130 thereon. As a result, the adhesion between the copper layer 130 and an underlayer may increase. Therefore, it is possible to suppress or prevent the copper layer 130 from being peeled off or separated from the underlayer, and as a result, there is an effect of improving electrical properties of the electrode.

### INDUSTRIAL APPLICABILITY

According to embodiments of the inventive concept, in forming an electrode including a ruthenium layer and a copper layer, it is possible to improve adhesion between the ruthenium layer and the copper layer. Therefore, it is possible to suppress or prevent the copper layer from being peeled off or separated from the ruthenium layer. As a result, it is possible to lower specific resistance of the electrode, and to improve electrical conductivity.

1. A method for forming an electrode on a substrate, the method comprising:
forming a ruthenium layer on a substrate by performing n times of a ruthenium layer formation cycle including spraying a ruthenium-containing precursor; and
forming a metal layer on the ruthenium layer by performing m times of a metal layer formation cycle including spraying a metal-containing precursor,
wherein the ruthenium layer formation cycle and the metal layer formation cycle are sequentially performed, or the ruthenium layer formation cycle and the metal layer formation cycle are sequentially performed and repeated two or more times.

2. The method of claim 1, further comprising forming a copper layer on the metal layer after the ruthenium layer formation cycle and the metal layer formation cycle are sequentially performed and repeated two or more times, wherein the forming of the copper layer is performed n times.

3. The method of claim 1, wherein the ruthenium layer formation cycle comprises exposing the ruthenium layer to hydrogen plasma.

4. The method of claim 1, further comprising exposing the ruthenium layer to hydrogen plasma, wherein the exposing of the ruthenium layer to hydrogen plasma is performed between the ruthenium layer formation cycle and the metal layer formation cycle.

5. The method of claim 1, wherein the metal layer formation cycle comprises exposing the metal layer to hydrogen plasma.

6. The method of claim 1, further comprising exposing the metal layer to hydrogen plasma, wherein the exposing of the metal layer to hydrogen plasma is performed after the end of the metal layer formation cycle.

7. A method for forming an electrode on a substrate, the method comprising:
forming a metal layer on a substrate by performing m times of a metal layer formation cycle including spraying a metal-containing precursor; and
forming a ruthenium layer on the metal layer by performing n times of a ruthenium layer formation cycle including spraying a ruthenium-containing precursor,
wherein the metal layer formation cycle and the ruthenium layer formation cycle are sequentially performed, or the metal layer formation cycle and the ruthenium layer formation cycle are performed by being sequentially performed and repeated two or more times.

8. The method of claim 7, further comprising forming a copper layer on the ruthenium layer after the metal layer formation cycle and the ruthenium layer formation cycle are sequentially performed and repeated two or more times, wherein the forming of the copper layer is performed n times.

9. The method of claim 7, wherein the metal layer formation cycle comprises exposing the metal layer to hydrogen plasma.

10. The method of claim 7, further comprising exposing the metal layer to hydrogen plasma, wherein the exposing of the metal layer to hydrogen plasma is performed between the metal layer formation cycle and the ruthenium layer formation cycle.

11. The method of claim 7, wherein the ruthenium layer formation cycle comprises exposing the ruthenium layer to hydrogen plasma.

12. The method of claim 7, further comprising exposing the ruthenium layer to hydrogen plasma, wherein the exposing of the ruthenium layer to hydrogen plasma is performed after the end of the ruthenium layer formation cycle.

13. A method for forming an electrode on a substrate, the method comprising forming a mixed layer containing ruthenium and a metal on a substrate by performing a cycle including spraying a ruthenium-containing precursor and a metal-containing precursor, wherein the cycle is performed and repeated one or more times.

14. The method of claim 13, further comprising forming a copper layer on the mixed layer after the above-described cycle is performed and repeated two or more times, wherein the forming of the copper layer is performed n times.

15. The method of claim 13, wherein the above-described cycle comprises exposing the mixed layer containing ruthenium and a metal to hydrogen plasma.

16. The method of claim 13, further comprising exposing the mixed layer containing ruthenium and a metal to hydrogen plasma, wherein the exposing of the mixed layer containing ruthenium and a metal to hydrogen plasma is performed after the end of the above-described cycle.

17. The method of claim 1, wherein the metal-containing precursor comprises at least one metal among tungsten, iridium, osmium, rhodium, platinum, silver, rhenium, or palladium.
